(19) United States
(12) Patent Application Publication
(10) Pub. No.: US 2008/0142811 A1
(43) Pub. Date: Jun. 19, 2008

(54) MOSFET devices and methods of fabrication

(75) Inventors: Kevin Sean Matocha, Rexford, NY (US); Larry Burton Rowland, Scotia, NY (US)

Correspondence Address: GENERAL ELECTRIC COMPANY (PCPI);C/O FLETCHER YODER, P. O. BOX 692289, HOUSTON, TX, 77269-2289, US

(73) Assignee: General Electric Company

(21) Appl. No.: 11/637,991

(22) Filed: Dec. 13, 2006

(51) Int. Cl. H01L 29/24; H01L 29/78; H01L 21/336

(52) U.S. Cl. 257/77; 257/329; 438/268; 257/E29.104; 257/E29.257; 257/E21.41

(57) ABSTRACT

A vertical MOSFET is disclosed. The MOSFET includes a gate dielectric region, a drift region having a drift region dopant concentration profile of a first conductivity type, and a JFET region having a JFET region dopant concentration profile of the first conductivity type adjacent to the gate dielectric region and disposed over the drift region. The JFET region dopant concentration profile is different from the drift region dopant concentration profile. A method for fabricating a vertical MOSFET is also disclosed.

### BACKGROUND

The invention relates generally to MOSFET devices and more particularly to vertical MOSFET devices.

High-power metal-oxide-semiconductor field effect transistor (MOSFET) devices are desirable for various power electronic applications. The input impedance of MOS devices is typically very high because of the insulator between the gate and the semiconductor channel. Because of the high input impedance, the gate leakage current is also very low. These qualities render the MOSFET highly desirable in power electronic applications.

Power MOSFETs advantageously have a vertical MOSFET structure with the source and drain formed at the top and bottom of the structure. The vertical scheme has the advantage of a large channel width and reduced electric field crowding at the gate. Power electronic devices based on wide bandgap semiconductors offer superior high voltage, high power, high temperature, and high frequency operation.

Wide band semiconductor materials such as SiC and GaN can advantageously be used in power MOSFETs. While SiC power devices are desirable due to their low on-resistance (thus low on-state power dissipation), their larger than expected output capacitance can be undesirable in power switching devices.

Accordingly, a technique is needed to address the high output capacitance in certain MOSFET devices.

### BRIEF DESCRIPTION

Briefly, in accordance with aspects of the present invention, a vertical MOSFET device is presented. The device includes a gate dielectric region, a drift region having a drift region dopant concentration profile of a first conductivity type, and a JFET region having a JFET region dopant concentration profile of the first conductivity type adjacent to the gate dielectric region and disposed over the drift region. The JFET region dopant concentration profile is different from the drift region dopant concentration profile.

In accordance with further aspects of the present invention, a SiC vertical MOSFET is presented. The vertical SiC MOSFET includes a gate dielectric region, a drift region having a uniform drift region dopant concentration profile of a first conductivity type, a JFET region positioned adjacent to the gate dielectric region and disposed over the drift region and having a uniform dopant concentration profile of the first conductivity type, a second conductivity type-well disposed over the drift region and positioned between the JFET region and a second conductivity body contact region; and a source region of the first conductivity type disposed over the second conductivity type-well.

In accordance with still further aspects of the present invention, a method for fabricating a vertical MOSFET is presented. The method includes forming a drift region having a drift region dopant concentration profile of a first conductivity type, and forming a JFET region having a JFET region dopant concentration profile of the first type conductivity type, wherein the drift region dopant concentration profile and the JFET region dopant concentration profile are different.

### DRAWINGS

These and other features, aspects, and advantages of the present invention will become better understood when the following detailed description is read with reference to the accompanying drawings in which like characters represent like parts throughout the drawings, wherein:

FIG. 1 is a cross-sectional representation of an exemplary embodiment of a vertical MOSFET according to aspects of the present invention;

FIG. 2 is a cross-sectional representation of a simulation of an exemplary embodiment of a vertical MOSFET according to aspects of the present invention;

FIG. 3 is a graph illustrating the variation in output capacitance versus drift voltage profile with drift region doping concentration for the simulated exemplary embodiment of FIG. 2;

FIG. 4 is a graph illustrating the variation in output capacitance versus drift voltage profile with drift region doping concentration for the simulated exemplary embodiment of FIG. 2; and

FIG. 5 is a graph illustrating the variation in output capacitance versus drift voltage profile with drift region doping concentration for another simulated exemplary embodiment of FIG. 2.

### DETAILED DESCRIPTION

Embodiments of the present invention disclose vertical MOSFET devices and methods for fabricating such devices.

A MOSFET is field effect transistor including a MOS (Metal-Oxide-semiconductor) capacitance structure. In a MOSFET, the MOS structure is formed by a gate electrode, a gate dielectric layer, and a semiconductor layer.

In one embodiment of the present invention a vertical MOSFET including a drift region having a drift region dopant concentration profile of a first conductivity type and a JFET region having a JFET region dopant concentration profile also of a first conductivity type is provided. The JFET region dopant concentration profile is different from the drift region dopant concentration profile. In one example, the JFET region dopant concentration is in a range from about 3×10¹⁵ cm⁻³ to about 2×10¹⁶ cm⁻³ and the drift region concentration is in a range from about 5×10¹⁴ cm⁻³ to about 3×10¹⁵ cm⁻³.

In one embodiment, the MOSFET device exhibits low specific output capacitance, about 1100 pF/cm² at a drain bias of 300 Volts. The output capacitance C_{OSS} is given by the sum of the drain to source capacitance C_{DS} and the gate to drain capacitance C_{GD}. In one embodiment, the drain region dopant profile and dopant concentration may be varied to lower the output capacitance C_{OSS}. In a further embodiment, the JFET region dopant profile and concentration and the drain region dopant profile and concentration may be varied to lower C_{OSS}.

In another embodiment, the MOSFET device exhibits a low drain to source resistance R_{DS} also referred to as the “on-resistance.” In one embodiment, the MOSFET device exhibits a specific on-resistance in a range from about 1 to about 20 mOhm-cm². There is typically a significant contribution to the R_{DS} from the JFET region resistance R_{JFET}. In one embodiment, the JFET region dopant profile concentration may be varied with respect to the drift region dopant concentration profile to lower the R_{JFET}.

In one embodiment of the present invention, the vertical MOSFET of the present invention exhibits both a low output capacitance and low on-resistance. In one embodiment, this is achieved by selecting certain combinations of JFET region dopant concentration profiles and drift region dopant concentration profiles.

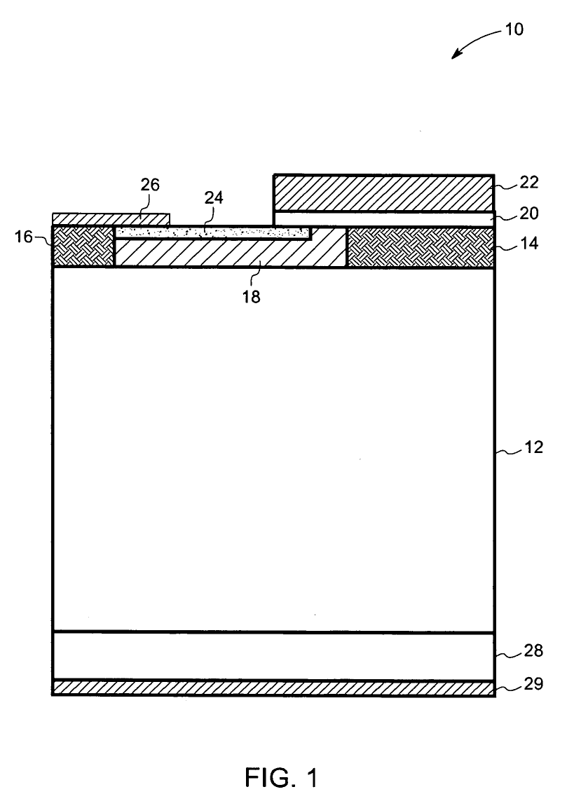

Referring to FIG. 1, an exemplary embodiment of a semiconductor device 10 is illustrated. In the illustrated embodiment, the semiconductor device 10 is shown to include a drift region 12 of a first conductivity type, for example n-type, and a JFET region 14 of the first conductivity type. In one example, the JFET region 14 and drift region 12 form a unitary structure without any interface but with different dopant concentration profiles. The MOSFET 10 further includes a heavily doped (for example p+) body contact region 16 and a well region 18 both of a second conductivity type, for example p-type. The body contact region 16 is disposed over the drift region 12 and adjacent to the well region 18, which is also disposed over the drift region 12 and is adjacent to the JFET region 14.

In the illustrated embodiment, a gate dielectric 20 is partially disposed over the JFET region 14, the well region 18 and a heavily doped (for example n+) source region 24. A gate electrode 22 is disposed in contact with the gate dielectric 20 and a source contact 26 is disposed in contact with the source region 24. A drain region 28 is formed at the lower end of the drift region 12 and a drain contact 29 is formed in contact with the drain region 28.

Although the embodiments described herein have been described with respect to certain structural embodiments of a vertical MOSFET, the invention is not restricted to the structural embodiments described here. All vertical MOSFET structures having drift and JFET regions fall within the scope of this invention.

In one embodiment, the JFET region 14 has a uniform dopant concentration profile. As used herein, a “uniform dopant concentration profile” refers to a concentration profile that does not vary by more than plus or minus 20% of the average dopant concentration. In another embodiment, the drift region 12 has a uniform dopant concentration profile. In a further embodiment, both the JFET and drift regions 14 and 16 have uniform but different dopant concentrations. For example, the JFET region dopant concentration is about 9×10¹⁵ cm⁻³ and the drift region dopant concentration is 3×10¹⁵ cm⁻³.

In some embodiments of the present invention, the drift region 12 has a non-uniform dopant concentration profile. In one embodiment, the drift region 12 has a graded dopant concentration profile. As used herein, the term “graded dopant concentration” refers to a concentration profile that varies along the thickness of a region. In one example, the graded dopant concentration profile is a step graded profile, wherein the drift region comprises two or more regions of different concentration, wherein the concentration changes abruptly at the interface of the two or more regions from one concentration to the other.

In another embodiment of the present invention, the drift region 12 exhibits a linearly graded dopant concentration profile, where the concentration changes linearly through the thickness of drift region 12. For example, the dopant concentration at the JFET end of the drift region 12 (that is, the region closest to the interface between the JFET region 14 and the drift region 12) is 1×10¹⁵ cm⁻³, and the concentration varies linearly through the thickness of the region 12 and at the drain end of the drift region 12 (that is, the region closest to the interface between the drift region 12 and the drain 28), the dopant concentration is 9×10¹⁵ cm⁻³.

In still another embodiment of the present invention, the drift region concentration varies non-linearly. In one example, the drift region 12 exhibits a parabolically varying dopant concentration profile from the JFET end of the drift region 12 to a drain end of the drift region.

In some embodiments of the present invention, in a graded or varying concentration profile, the concentration at the JFET end of the drift region 12 is lower than a dopant concentration at the drain end of the drift region 12. In alternate embodiments, the concentration at the JFET end of the drift region 12 is lower than a dopant concentration at the drain end of the drift region 12.

In one embodiment of the present invention, the JFET region thickness is in a range from about 100 nm to about 1 micron. In a further embodiment, the JFET region thickness is in a range from about 0.4 microns to 0.8 microns.

In one embodiment of the present invention, a drift region thickness is in a range from about 1 micron to about 150 microns. In a further embodiment, the drift region thickness is in a range from about 5 to 15 microns.

In one embodiment, the JFET region concentration is higher than the drift region concentration. In an alternate embodiment, the drift region concentration is higher than the JFET region concentration.

In one embodiment, the first conductivity type is p-type and the second conductivity type is n-type. Alternatively, the first conductivity type is n-type and the second conductivity type is p-type.

Non-limiting examples of semiconductor materials used to form the different MOSFET regions include silicon carbide (SiC), or group III nitrides, such as gallium nitride (GaN). In one embodiment, the MOSFET is a SiC MOSFET. In another embodiment, the MOSFET is an AlₓIn_{y}Ga_{1-x-y}N MOSFET, where 0≦x+y≦1.

In another embodiment of the present invention is a method for fabricating a vertical MOSFET. The method includes forming a drift region having a drift region dopant concentration profile of a first conductivity type, and forming a JFET region having a JFET region dopant concentration profile of the first conductivity type. The drift region dopant concentration profile and the JFET region dopant concentration profile are different.

In one embodiment, a desired drift region dopant concentration profile is achieved during epitaxial growth of the drift region. Non-limiting examples of epitaxial growth techniques include chemical vapor deposition, molecular beam epitaxy, atomic layer deposition, and metal organic vapor phase epitaxy. In one example, the dopant/dopant precursor levels are varied during the growth to achieve a desired concentration profile, such as for example, a graded dopant profile, through a thickness of the drift or JFET regions.

Another technique that may be advantageously used to form a drift region or JFET region with a desired dopant profile is ion implantation. In one example, the drift region or JFET region could be epitaxially grown with or without doping and ion implantation could be used to modify the doping levels in the region.

In another embodiment, diffusion doping is used to form a drift region or JFET region with a desired dopant profile. In one example, a drift region or a JFET region could be epitaxially grown with or without doping and a diffusion process, such as thermal diffusion, could be used to modify the doping levels in the region. For example, a drive-in diffusion process, whereby a series of diffusion steps are used to drive the dopants into the thickness of the region, may be used to create a graded dopant profile in the region.

In some embodiments, a combination of the various doping techniques may be used to obtain a desired dopant profile in a region. For example, a combination of epitaxial growth, ion implantation and dopant diffusion may be used to achieve a parabolically graded drift region.

The drift and JFET regions may be formed to have a uniform concentration profile, or a non-uniform concentration profile. In one example, the drift and/or the JFET regions are formed to have a graded profile such as but not limited to a step graded profile, linearly graded concentration profile, a parabolically graded concentration profile or combinations of these profiles.

Embodiments of the present invention include methods for fabricating a vertical MOSFET device. In one embodiment, the drift region of the MOSFET is epitaxially grown on a semiconductor substrate. The JFET region is then grown epitaxially on the drift-region. The two epitaxial growth steps can be performed in a single, continuous epitaxial run, where the dopant concentration of the drift and JFET regions can be controlled to provide the desired doping concentration profile. In one embodiment, this is followed by the formation of a p-well region by ion implantation. The n+ source region is formed by ion implantation and the p+ body-contact region is also formed by ion implantation. The ion-implants are then activated by high-temperature annealing, for example at 1675° C. for 30 minutes with the semiconductor surface covered by a graphite cap. Next, the gate dielectric is formed by thermal oxidation or by chemical vapor deposition. The gate electrode is deposited and patterned. Finally, the source ohmic contact and drain contact metals are deposited and annealed.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

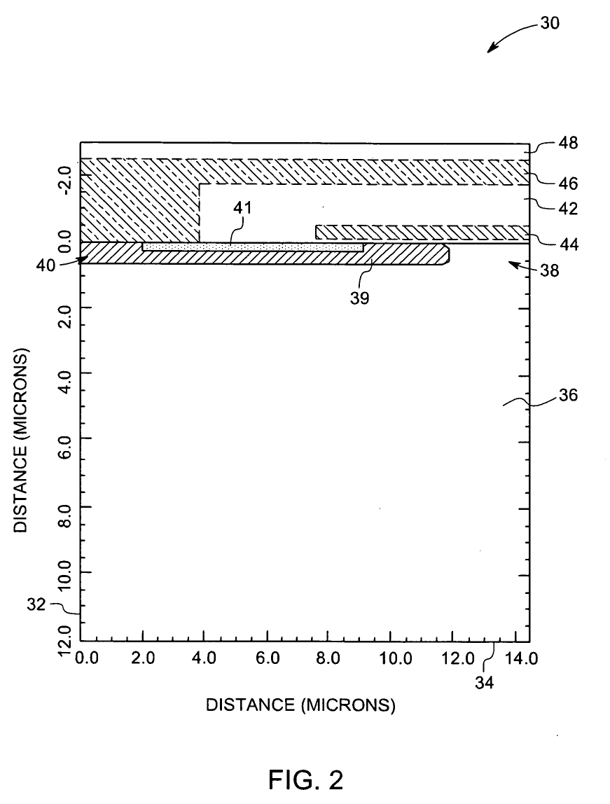

In one embodiment of the present invention, a SiC MOSFET 30 illustrated in FIG. 2 was simulated using Medici™ device simulation software. The Y-axis 32 represents the thickness of the MOSFET regions (in microns) and the X-axis 34 represents the width of the MOSFET regions (in microns). The MOSFET 30 includes a drift region 36 and a JFET region 38 of n-type conductivity. A p-well region 39 and a p+ body contact region 40 are disposed over the drift region 36. The MOSFET further includes n+ source region 41, a gate dielectric 42, a gate electrode 44, a source contact 46 and a dielectric 48.

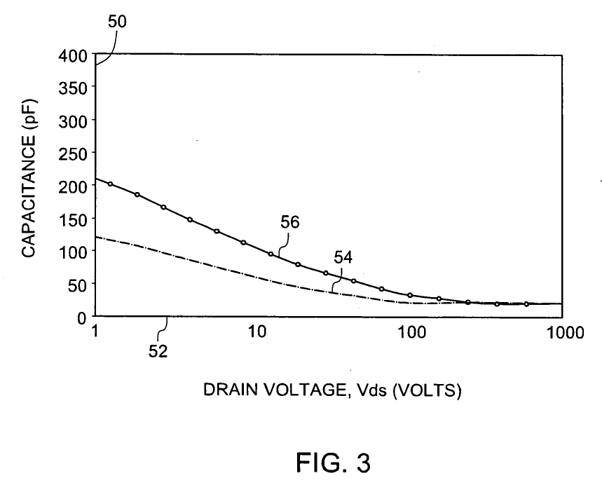

FIG. 3 illustrates the variation in the output capacitance 50 with drain voltage 52 for different drift and JFET region dopant concentrations. In this example, the drift and the JFET region were modeled to have a uniform dopant distribution and the same dopant concentration. Line 54 indicates the change in the output capacitance with drain voltage for a dopant concentration of 1×10¹⁵ cm⁻³ (sample 1) and line 56 indicates the change in the output capacitance with drain voltage for a dopant concentration of 3×10¹⁵ cm⁻³ (sample 2). Comparison of lines 54 and 56 point to a lower output capacitance at lower drain region dopant concentration.

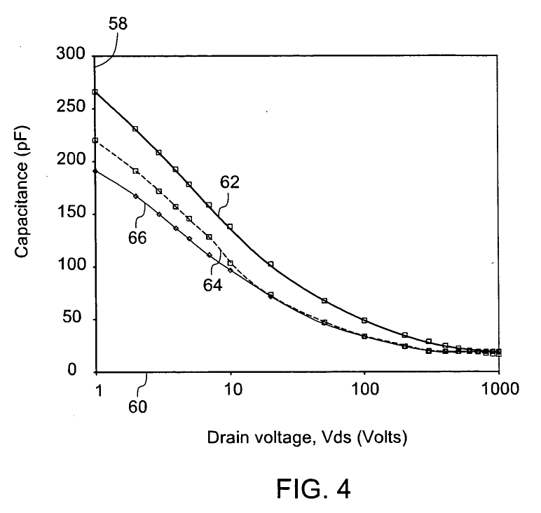

FIG. 4 illustrates the variation in the output capacitance 58 with drain voltage 60 for different dopant concentrations of the drift and JFET regions. In this example, the drift and JFET regions were both modeled to have uniform dopant concentrations through their thickness.

Line 62 indicates the change in the output capacitance with drain voltage for a JFET and drift dopant concentration of 9×10¹⁵ cm⁻³ (sample 3). For this combination of JFET and drift dopant profiles, the specific on-resistance Rₛₚ was estimated to be 7.9 mOhm-cm².

Line 64 indicates the change in the output capacitance with drain voltage for a drift dopant concentration of 3×10¹⁵ cm⁻³ and JFET region dopant concentration of 9×10¹⁵ cm⁻³ (sample 4). For this combination of JFET and drift dopant profiles, the specific on-resistance was estimated to be 10.4 mOhm-cm².

Line 66 indicates the change in the output capacitance with drain voltage for a JFET and drift dopant concentration of 3×10¹⁵ cm⁻³ (sample 5). For this combination of JFET and drift dopant profiles, the specific on-resistance Rₛₚ was estimated to be 12.4 mOhm-cm².

Although comparison of lines 62, 64, and 66, point to a lower output capacitance at a lower drain region dopant concentration (line 62), the estimated specific on-resistance Rₛₚ is lowest for the configuration of line 62. In some embodiments, it is important to have a combination of low output capacitance and low specific resistance. The product of the on-resistance (calculated from the specific resistance using a device area of 1.77×10⁻² cm²) and the output capacitance at a drain voltage of 300 volts can provide a measure of this. For sample 3, the product of the on-resistance and output capacitance is calculated to be 12.6 Ohm-pF, for sample 4, the product of the on-resistance and output capacitance is calculated to be 11.3 Ohm-pF, an for sample 5, the product of the on-resistance and output capacitance is calculated to be 13.6 Ohm-pF. Therefore, the dopant concentration profiles can be varied to provide a desired output capacitance and/or desired on-resistance.

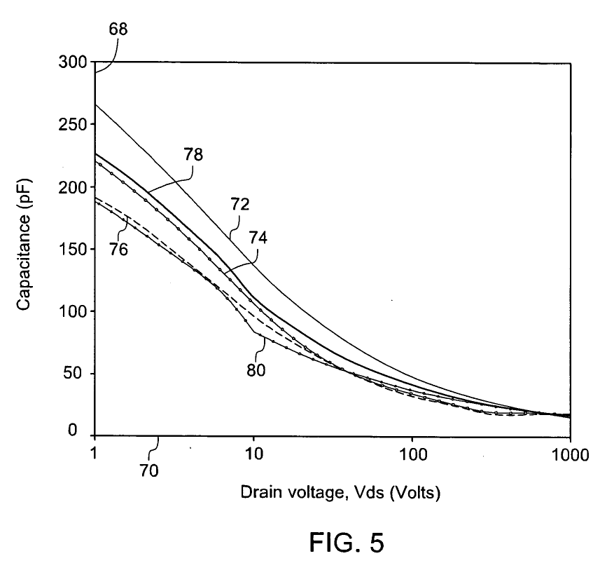

FIG. 5 illustrates the variation in the output capacitance 68 with drain voltage 70 for different dopant concentration profiles of the drift and JFET regions. In these examples, the drift regions were modeled to have uniform or linearly graded dopant concentration profiles and the JFET regions were modeled to have uniform dopant concentrations through their thickness.

Line 72 indicates the change in the output capacitance with drain voltage for a JFET and drift uniform dopant concentration of 9×10¹⁵ cm⁻³ (sample 6). For this combination of JFET and drift dopant profiles, the specific on-resistance Rₛₚ was estimated to be 7.9 mOhm-cm². The product of the on-resistance (calculated from the specific resistance using a device area of 1.77 10⁻² cm²) and capacitance at 300 V was estimated to be 12.6 Ohm-pF. The product of the on-resistance and capacitance at 50 V was estimated to be 30.1 Ohm-pF.

Line 74 indicates the change in the output capacitance with drain voltage for a uniform drift dopant concentration of 3×10¹⁵ cm⁻³ and a uniform JFET region dopant concentration of 9×10¹⁵ cm⁻³ (sample 7). For this combination of JFET and drift dopant profiles, the specific on-resistance was estimated to be 10.4 mOhm-cm². The product of the on-resistance and capacitance at 300 V was estimated to be 11.3 Ohm-pF. The product of the on-resistance and capacitance at 50 V was estimated to be 27.4 Ohm-pF.

Line 76 indicates the change in the output capacitance with drain voltage for a JFET and drift dopant concentration of 3×10¹⁵ cm⁻³ (sample 8). For this combination of JFET and drift dopant profiles, the specific on-resistance Rₛₚ was estimated to be 12.4 mOhm-cm². The product of the on-resistance and capacitance at 300 V was estimated to be 13.6 Ohm-pF. The product of the on-resistance and capacitance at 50 V was estimated to be 32.4 Ohm-pF.

Line 78 indicates the change in the output capacitance with drain voltage for a linearly graded drift region with a dopant concentration of 3×10¹⁵ cm⁻³ at JFET end of the region linearly varying to a dopant concentration of 9×10¹⁵ cm⁻³ at the drain end of the drift region. The JFET region was modeled with a uniform dopant concentration of 9×10¹⁵ cm⁻³ (sample 8). For this combination of JFET and drift dopant profiles, the specific on-resistance was estimated to be 8.7 mOhm-cm². The product of the on-resistance and capacitance at 300 V was estimated to be 13.2 Ohm-pF. The product of the on-resistance and capacitance at 50 V was estimated to be 27.4 Ohm-pF.

Line 80 indicates the change in the output capacitance with drain voltage for a linearly graded drift region with a dopant concentration of 1×10¹⁵ cm³ at JFET end of the region linearly varying to a dopant concentration of 9×10¹⁵ cm³ at the drain end of the drift region. The JFET region was modeled with a uniform dopant concentration of 9×10¹⁵ cm⁻³ (sample 9). For this combination of JFET and drift dopant profiles, the specific on-resistance was estimated to be 10.0 mOhm-cm². The product of the on-resistance and capacitance at 300 V was estimated to be 14.2 Ohm-pF. The product of the on-resistance and capacitance at 50 V was estimated to be 26.6 Ohm-pF.

Comparing the voltage versus capacitance line profiles, the calculated specific on-resistance, and the estimated product, it is seen that different combinations of drain region and JFET regions dopant profiles can provide different advantages at different voltages. For example, sample 9 having a linearly graded drift region has a comparatively lower on-resistance-capacitance product (R*C) of 26.6 Ohm-pF, although at 300 V, this sample exhibits a comparatively high R*C of 14.2 ohms. Therefore, the dopant concentration profiles can be varied to provide a desired output capacitance and desired on-resistance.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A vertical MOSFET comprising:
a gate dielectric region;
a drift region having a drift region dopant concentration profile of a first conductivity type; and
a JFET region having a JFET region dopant concentration profile of the first conductivity type adjacent to the gate dielectric region and disposed over the drift region;
wherein the JFET region dopant concentration profile is different from the drift region dopant concentration profile.

2. The vertical MOSFET of claim 1, wherein a JFET dopant concentration profile comprises a uniform dopant concentration.

3. The vertical MOSFET of claim 1, wherein the drift region dopant concentration profile comprises a uniform dopant concentration.

4. The vertical MOSFET of claim 3, wherein the JFET region dopant concentration profile comprises a uniform dopant concentration, wherein a drift region dopant concentration is different from a JFET region dopant concentration.

5. The vertical MOSFET of claim 1, wherein the drift region dopant concentration profile comprises a non-uniform dopant concentration profile.

6. The vertical MOSFET of claim 1, wherein the drift region dopant concentration profile comprises a graded dopant concentration profile.

7. The vertical MOSFET of claim 6, wherein the graded dopant concentration profile comprises a step graded profile comprising two or more regions of uniform but different dopant concentrations.

8. The vertical MOSFET of claim 6, wherein the graded dopant concentration profile comprises a linearly graded profile comprising a linearly varying dopant concentration from a JFET end of the drift region to a drain end of the drift region.

9. The vertical MOSFET of claim 6, wherein the graded dopant concentration profile comprises a parabolically graded profile comprising a parabolically varying dopant concentration from a JFET end of the drift region to a drain end of the drift region.

10. The vertical MOSFET of claim 6, wherein a dopant concentration at a JFET end of the drift region is lower than a concentration at a drain end of the drift region.

11. The vertical MOSFET of claim 1, wherein a dopant concentration of the JFET region is higher than a dopant concentration of the drift region.

12. The vertical MOSFET of claim 1, wherein a JFET region dopant concentration is in a range from about 3×10¹⁵ cm⁻³ to about 2×10¹⁶ cm⁻³.

13. The vertical MOSFET of claim 1, wherein a drain region dopant concentration is in a range from about 5×10¹⁴ cm⁻³ to about 3×10¹⁵ cm⁻³.

14. The vertical MOSFET of claim 1, wherein a JFET region thickness is in a range from about 10 nm to about 1 micron.

15. The vertical MOSFET of claim 1, wherein a drift region thickness is in a range from about 5 microns to about 150 microns.

16. The vertical MOSFET of claim 1, wherein a specific output capacitance is in a range from about 1000 to 3000 pF/cm² at a source to drain voltage of 300 Volts.

17. The vertical MOSFET of claim 1, wherein a specific on-resistance is in a range from about 1 to 100 mΩ-cm².

18. The vertical MOSFET of claim 1, comprising a well region of second conductivity type disposed over the drift region and positioned between the JFET region and a second conductivity body contact region.

19. The vertical MOSFET of claim 18, further comprising a source region of first conductivity type disposed over the well region of second conductivity type.

20. The vertical MOSFET of claim 1, wherein the first conductivity type is n-type and the second conductivity type is p-type.

21. The vertical MOSFET of claim 1, wherein the first conductivity type is p-type and the second conductivity type is n-type.

22. The vertical MOSFET of claim 1, wherein the MOSFET is a SiC MOSFET.

23. The vertical MOSFET of claim 1, wherein the MOSFET is an AlₓIn_{y}Ga_{1-x-y}N MOSFET, wherein 0≦x+y≦1.

24. The vertical MOSFET of claim 1, wherein the JFET region and the drift region form a unitary structure.

25. A vertical SiC MOSFET comprising:
a gate dielectric region;
a drift region having a uniform drift region dopant concentration profile of a first conductivity type;
a JFET region positioned adjacent to the gate dielectric region and disposed over the drift region and having a uniform dopant concentration profile of the first conductivity type;
a second conductivity type-well disposed over the drift region and positioned between the JFET region and a second conductivity body contact region; and
a source region of the first conductivity type disposed over the second conductivity type-well.

26. A method for fabricating a vertical MOSFET comprising:
forming a drift region having a drift region dopant concentration profile of a first conductivity type; and
forming a JFET region having a JFET region dopant concentration profile of the first conductivity type;
wherein the drift region dopant concentration profile and the JFET region dopant concentration profile are different.

27. The method of claim 26, wherein a drift region dopant concentration profile comprises a profile comprising uniform dopant concentration profile, non-uniform dopant concentration profile, step graded concentration profile, linearly graded concentration profile, parabolically graded concentration profile or combinations thereof.

28. The method of claim 26, wherein the drift region dopant concentration profile is formed during epitaxial growth.

29. The method of claim 26, wherein the drift region dopant concentration profile is formed by dopant diffusion.

30. The method of claim 26, wherein the drift region dopant concentration profile is formed by ion implantation.

31. The method of claim 26, wherein the drift region dopant concentration profile is formed by a combination of two or more of ion implantation, dopant diffusion, and epitaxial growth.

32. The method of claim 26, wherein forming a drift region and forming a JFET region comprises forming a unitary structure with a first region with a drift region concentration profile and a second region with a JFET region dopant profile.
